(19) United States
(12) Patent Application Publication
(10) Pub. No.: US 2016/0195808 A1
(43) Pub. Date: Jul. 7, 2016

(54) REAGENT FOR ENHANCING GENERATION OF CHEMICAL SPECIES

(71) Applicant: TOYO GOSEI CO., LTD., Ichikawa-shi, Chiba (JP)

(72) Inventor: Satoshi Enomoto, Inzai-shi, Chiba (JP)

(21) Appl. No.: 14/912,027

(22) PCT Filed: Aug. 13, 2014
(86) PCT No.: PCT/JP2014/004187

§ 371 Date: Feb. 12, 2016

Related U.S. Application Data
(60) Provisional application No. 61/865,946, filed on Aug. 14, 2013.

(51) Int. Cl. G03F 7/004; G03F 7/20

(52) U.S. Cl. CPC G03F 7/0045; G03F 7/203

(57) ABSTRACT

A reagent that enhances acid generation of a photoacid generator and composition containing such reagent is disclosed.

### CROSS-REFERENCE TO RELATED APPLICATIONS

This application is a national phase entry under 35 U.S.C. §371 of International Patent Application PCT/JP2014/004187, filed Aug. 13, 2014, designating the United States of America and published in English as International Patent Publication WO 2015/022779 A1 on Feb. 19, 2015, which claims the benefit under Article 8 of the Patent Cooperation Treaty and under 35 U.S.C. §119(e) to U.S. Provisional Patent Application Ser. No. 61/865,946 filed on Aug. 14, 2013, the disclosure of each of which is hereby incorporated herein in its entirety by this reference.

### TECHNICAL FIELD

Several aspects of this disclosure relate to the fields of a reagent that can produce an intermediate enhancing a generation of a chemical species such as acid and base from a precursor. Such intermediate can transfer its energy or electron to the precursor or receive the precursor's energy or electron to generate the chemical species.

### BACKGROUND

Current high-resolution lithographic processes are based on chemically amplified resists (CARs) and are used to pattern features with dimensions less than 100 nm.

A method for forming pattern features with dimensions less than 100 nm is disclosed in U.S. Pat. No. 7,851,252 (filed on Feb. 17, 2009), the contents of the entirety of which are incorporated herein by this reference.

### BRIEF SUMMARY

A reagent that can produce an intermediate enhancing generation of a chemical species, such as acid, and a composition are disclosed. Typically, such intermediate assists the generation of Bronsted acid or base from a precursor. Furthermore, such reagent can apply to the generation of Lewis acid and base. Typically, such intermediate is formed by an irradiation of the reagent with an electromagnetic ray or a particle ray. More typically, an extreme ultraviolet light (EUV) and electron beam (EB) are used for such electromagnetic ray or particle ray, respectively.

An excitation of such intermediate during its lifetime can make electron transfer from the intermediate to the precursor or from the precursor to the intermediate become facile, even if the precursor does not have enough electron-accepting ability or the intermediate does not have enough electron-donating ability. The precursor generates such chemical species through the electron transfer involved with the intermediate.

Such reagent may have a protecting group for the carbonyl group of the ketone compound or hydroxy group of the alcohol compound. Typically, the ketone compound or alcohol compound is generated by deprotection reaction of the reagent by acid generated from a photoacid generator. The ketone compound or alcohol compound generates an intermediate such as ketyl radical. The excitation of ketyl radical may transfer its electron to the photoacid generator even if the photoacid generator does not have enough electron-accepting ability in its ground state or the ketyl radical does not have enough electron-donating ability. The photoacid generator generates acid by receiving the electron from the excited intermediate in its ground state.

A product formed by excitation of an intermediate such as ketyl radical can also enhance a generation of the chemical species from the precursor as a sensitizer. An excitation of the ketyl radical results in a corresponding ketone compound, which can act as a sensitizer for the generation of acid from the photoacid generator.

A composition, containing such reagent that is to form such intermediate, a precursor that is to form a chemical species, and a compound that is to react with the chemical species, can be applied as photoresist to the manufacturing method of electronic devices such as semiconductor devices and electro-optical devices. For example, after a coating film of the composition is exposed to an excimer laser, an EUV light or an EB in a first step, an irradiation of the coating film is carried out during a lifetime of the intermediate that has been generated in the first step. In the second step, the coating film can be exposed to a light, the wavelength of which is longer than that of the EUV light, an UV light, the wavelength of which is longer than 200 nm, or a visible light.

Further, a third step can be performed to excite a product generated through the excitation of the intermediate. The product can act as sensitizer for enhancing the generation of the chemical species from the precursor. The composition can be used as a chemically amplified photoresist containing a photoacid generator and a resin containing a protective group such as ester and ether group, which is to decompose by reacting with acid generated from the photoacid generator.

It is preferred that in order to attain the high resolution lithographic property, an unexposure area in the first step is inactive to the light or the particle ray with which the intermediate is irradiated in the second step.

A reagent relating to an aspect of this disclosure is characterized wherein an intermediate is generated from the reagent; and a generation of a first chemical species from a precursor is enhanced by a first irradiation of the intermediate with at least one of a first electromagnetic ray, the wavelength of which is a first wavelength and a first particle ray.

With regard to the reagent, it is preferred that the intermediate is a reactive intermediate such as radical and ion.

With regard to the reagent, it is preferred that the intermediate is generated from the reagent by a second irradiation of the reagent or a composition containing the reagent with at least one of a second electromagnetic ray, the wavelength of which is a second wavelength and a second particle ray.

With regard to the reagent, it is preferred that the first wavelength is longer than the second wavelength.

With regard to the reagent, it is preferred that the intermediate is oxidized by the first irradiation.

With regard to the reagent, it is preferred that the precursor receives an electron from the intermediate by the first irradiation.

With regard to the reagent, it is preferred that the intermediate is ketyl radical.

With regard to the reagent, it is preferred that a first moiety includes a protecting group and a second moiety includes a pi-conjugated system.

It is preferred that a deprotection reaction of the first moiety occurs by a reaction of the first moiety with the first chemical species to form the intermediate.

With regard to the reagent, it is preferred that the intermediate decays.

With regard to the reagent, it is preferred that a product is generated from the intermediate.

With regard to the reagent, it is preferred that the product acts as a sensitizer.

A composition relating to an aspect of this disclosure includes any one of the above reagents and the precursor.

With regard to the composition, it is preferred that the composition further includes the resin or high molecular weight compound, the molecular weight of which is higher than 2000.

With regard to the composition, it is preferred that a product is generated from the intermediate.

With regard to the composition, it is preferred that the product acts as a sensitizer for the generation of the first chemical species from the precursor.

A method for manufacturing a device relating to an aspect of this disclosure includes applying a solution of any one of the above compositions to a substrate, such that a coating film including the composition is formed on the substrate, and performing the first irradiation of the coating film.

With regard to the method, it is preferred that the first irradiation is carried out during a period a lifetime of the intermediate lives after the second irradiation is carried out.

With regard to the method, it is preferred that the method further includes: performing the second irradiation of the coating film such that a first portion of the coating film is irradiated with the at least one of a second electromagnetic ray and a second particle ray, while a second portion of the coating film is not irradiated with the at least one of the second electromagnetic ray and the second particle ray; and removing the first portion or the second portion.

With regard to the method, it is preferred that the second irradiation is performed prior to the first irradiation and the intermediate is generated by the second irradiation.

With regard to the method, it is preferred that the method further includes performing a third irradiation of the coating film with at least one of a third electromagnetic ray and a third particle ray after performing the first irradiation.

With regard to the method, it is preferred that a product generated from the intermediate is excited by the third irradiation.

With regard to the method, it is preferred that the method further includes etching the substrate such that a third portion of the substrate on which the first portion has been present is etched.

### BRIEF DESCRIPTION OF THE DRAWING

In the drawings, which illustrate what is currently considered to be the best mode for carrying out the disclosure:

FIG. 1 shows fabrication processes of a device such as integrated circuit (IC) using photoresist including an acid-generation enhancer.

### DETAILED DESCRIPTION

### Experimental Procedures

### Synthesis of 4-hydropyranylacetophenone

10.0 g of 4-hydroxyacetophenone and 9.89 g of 2H-dihydropyran are dissolved in 80.0 g of methylene chloride. 0.74 g of pyridinium p-toluenesulfonate is added to the methylene chloride solution containing 4-hydroxyacetophenone and 2H-dihydropyran. The mixture is stirred at 25 degrees Celsius for 3 hours. Thereafter, the mixture is further stirred after addition of 1% aqueous solution of sodium hydroxide. The organic phase is collected through separation by liquid extraction. 14.4 g of 4-hydropyranylacetophenone is obtained by evaporating solvents from the collected organic phase.

### Synthesis of 1-(4-tetrahydropyranylphenyl)ethanol

### Example 1

5.0 g of 4-hydropyranylacetophenone and 0.10 g of potassium hydroxide are dissolved in ethanol. 1.04 g of sodium boronhydride is added to the ethanol solution containing 4-hydropyranylacetophenone and potassium hydroxide. The mixture is stirred at 25 degrees Celsius for 3 hours. Thereafter, alkali in the mixture is neutralized by 10% aqueous solution of hydrochloric acid. The organic phase is collected through separation by liquid extraction using 100 g of methylene chloride. 4.52 g of 1-(4-Tetrahydropyranylphenyl)ethanol is obtained by evaporating solvents from the organic phase.

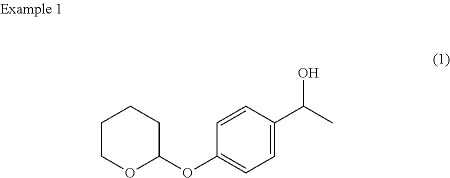 [SMILES: CC(O)c1ccc(OC2CCCCO2)cc1]

### Synthesis of 2,4-dimethoxy-4′-methoxybenzophenone

200 g of 2,4-dihydroxy-4′-hydroxybenzophenone, 1.95 g of dimethyl sulfate and 2.14 g of potassium carbonate are dissolved in 16.0 g of acetone. The mixture is stirred at reflux temperature for 8 hours. Next, the mixture is cooled to 25 degrees Celsius and it is further stirred after addition of 80.0 g of water, then extracted with 20.0 g ethyl acetate and the organic phase washed with water. Thereafter, ethyl acetate is distilled away, and the resultant is purified by silica gel column chromatography (ethyl acetate: hexane=3:97), thereby obtaining 1.43 g of 2,4-dimethoxy-4′-methoxybenzophenone.

### Synthesis of (2,4-dimethoxyphenyl)-(4′-methoxyphenyl)-methanol

### Example 2

1.0 g of 2,4-dimethoxy-4′-methoxybenzophenone and 0.01 g of potassium hydroxide are dissolved in 12.0 g of methanol. 0.42 g of sodium boron hydride is added to the methanol solution. The mixture is stirred at reflux temperature for 3 hours. Next, the mixture is added to the 80 g of water and then extracted with 20.0 g ethyl acetate and the organic phase washed with water. Thereafter, ethyl acetate is distilled away, thereby obtaining 0.90 g of (2,4-dimethoxyphenyl)-(4′-methoxyphenyl)-methanol.

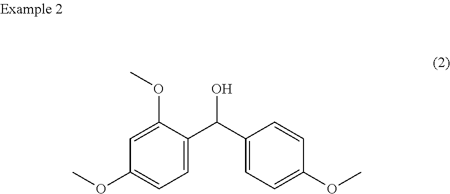

### Synthesis of 2,4-dimethoxy-4′-(2-vinyloxy-ethoxy)-benzophenone

2.00 g of 2,4-dimethoxy-4′-hydroxybenzophenone, 2.48 g of 2-chloroethyl vinyl ether and 3.21 g of potassium carbonate are dissolved in 12.0 g of DMF. The mixture is stirred at 110 degrees Celsius for 15 hours. Next, the mixture is cooled to 25 degrees Celsius, further stirred after addition of 60.0 g of water, then extracted with 24.0 g toluene and the organic phase washed with water. Thereafter, toluene is distilled away, thereby obtaining 3.59 g of 2,4-dimethoxy-4′-(2-vinyloxy)-ethoxy-benzophenone.

### Synthesis of 2,4-dimethoxy-4′-(2-hydroxy-ethoxy)-benzophenone

3.59 g of 2,4-dimethoxy-4′-(2-vinyloxy)-ethoxy-benzophenone, 0.28 g of pyridinium p-toluenesulfonate and 2.1 g of water are dissolved in 18.0 g of acetone. The mixture is stirred at 35 degrees Celsius for 12 hours. Next, the mixture is further stirred after addition of 3% aqueous solution of sodium carbonate, then extracted with 28.0 g ethyl acetate and the organic phase washed with water. Thereafter, ethyl acetate is distilled away, thereby obtaining 3.04 g of 2,4-dimethoxy-4′-(2-hydroxy-ethoxy-benzophenone).

### Synthesis of (2,4-dimethoxyphenyl)-[4′-(2-methacryloxy-ethyl)-phenyl]-benzophenone

3.0 g of 2,4-dimethoxy-4′-(2-hydroxy-ethoxy)-benzophenone and 1.7 g of methacrylic anhydride are dissolved in 21 g of tetrahydrofuran. 1.2 g of triethylamine dissolved in 3.6 g of tetrahydrofuran is added dropwise to the tetrahydrofuran solution containing 2,4-dimethoxy-4′-(2-hydroxy-ethoxy)-benzophenone over 10 minutes. Next, the mixture is stirred at 25 degrees Celsius for 3 hours, further stirred after addition of water, then extracted with 30 g ethyl acetate and the organic phase washed with water. Thereafter, ethyl acetate is distilled away, and the residue is purified by silica gel column chromatography (ethyl acetate: hexane=1:9), thereby obtaining 2.72 g of (2,4-dimethoxyphenyl)-[4′-(2-methacryloxy-ethyl)-phenyl]-benzophenone.

### Synthesis of (2,4-dimethoxyphenyl)-[4′-(2-methacryloxy-ethoxy)-phenyl]-methanol

2.7 g of (2,4-dimethoxyphenyl)-[4′-(2-methacryloxy-ethyl)-phenyl]-benzophenone is dissolved in 21.6 g of tetrahydrofuran. 0.55 g of sodium boron hydride dissolved in water is added to the tetrahydrofuran solution. The mixture is stirred at 25 degrees Celsius for 2 hours. Next, the mixture is added to the 120 g of water, then extracted with 20.0 g ethyl acetate and the organic phase washed with water. Thereafter, ethyl acetate is distilled away, thereby obtaining 2.4 g of (2,4-dimethoxyphenyl)-[4′-(2-methacryloxy-ethoxy)-phenyl]-methanol.

### Synthesis of 2-methyl-acrylic acid 2-{4-[(2,4-dimethoxy-phenyl)-(1-ethoxy-ethoxy)-methyl]-phenoxy}-ethyl ester

### Example 3

1.4 g of ethyl vinyl ether and 0.06 g of pyridinium p-toluenesulfonate are dissolved in 18.0 g of methylene chloride. 1.5 g of (2,4-dimethoxyphenyl)-[4′-(2-methacryloxy-ethyl)-phenyl)-methanol dissolved by 8.0 g of methylene chloride is added dropwise to the methylene chloride solution containing ethyl vinyl ether and pyridinium p-toluenesulfonate over 30 minutes. Next, the mixture is stirred at 25 degrees Celsius for 3 hours. The mixture is then further stirred after addition of 3% aqueous solution of sodium carbonate and the organic phase washed with water. Thereafter, methylene chloride is distilled away, and the resultants are purified by silica gel column chromatography (ethyl acetate: hexane=5:95), thereby obtaining 1.31 g of 2-{4-[(2,4-dimethoxy-phenyl)-(1-ethoxy-ethoxy)-methyl]-phenoxy}-ethyl ester.

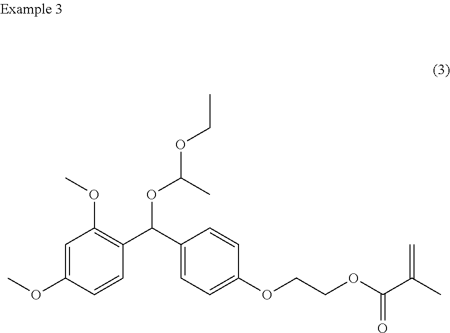 [SMILES: C=C(C)C(=O)OCCOc1ccc(C(OC(C)OCC)c2ccc(OC)cc2OC)cc1]

### Synthesis of 2-(2-vinyloxy-ethoxy)-thioxanthone

3.00 g of 2-hydroxy-thioxanthone, 2.80 g of 2-chloroethyl vinyl ether and 3.63 g of potassium carbonate are dissolved in 12.0 g of DMF. The mixture is stirred at 110 degrees Celsius for 15 hours. Next, the mixture is cooled to 25 degrees Celsius, further stirred after addition of 60.0 g of water, and then extracted with 24.0 g toluene and the organic phase washed with water. Thereafter, toluene is distilled away, thereby obtaining 3.69 g of 2-(2-vinyloxy-ethoxy)-thioxanthone.

### Synthesis of 2-(2-hydroxy-ethoxy)-thioxanthone

3.69 g of 2-(2-vinyloxy-ethoxy)-thioxanthone, 0.31 g of pyridinium p-toluenesulfonate and 2.2 g of water are dissolved in 18.5 g of acetone. The mixture is stirred at 35 degrees Celsius for 12 hours. Next, the mixture is further stirred after addition of 3% aqueous solution of sodium carbonate, then extracted with 28.0 g ethyl acetate and the organic phase washed with water. Thereafter, ethyl acetate is distilled away, thereby obtaining 3.10 g of 2-(2-hydroxy-ethoxy)-thioxanthone.

### Synthesis of 2-(2-methacryloxy-ethoxy)-thioxanthone

3.0 g of 2-(2-hydroxy-ethoxy)-thioxanthone and 1.7 g of methacrylic anhydride are dissolved in 21 g of tetrahydrofuran. 1.2 g of triethylamine dissolved in 3.0 g of tetrahydrofuran is added dropwise to the tetrahydrofuran solution containing 2-(2-hydroxy-ethoxy)-thioxanthone over 10 minutes. Next, the mixture is stirred at 25 degrees Celsius for 3 hours, further stirred after addition of water, then extracted with 28 g ethyl acetate and the organic phase washed with water. Thereafter, ethyl acetate is distilled away and the residue is purified by silica gel column chromatography (ethyl acetate: hexane=5:95), thereby obtaining 2.77 g of 2-(2-Methacryloxy-ethoxy)-thioxanthone.

### Synthesis of 2-methyl-acrylic acid 2-(9-hydroxy-9H-thioxanthen-2-yloxy)-ethyl ester

### Example 4

3.0 g of 2-(2-methacryloxy-ethoxy)-thioxanthone is dissolved in 21.6 g of tetrahydrofuran. 0.60 g of sodium boron hydride is added to the methanol solution. The mixture is stirred at 25 degrees Celsius for 6 hours. Next, the mixture is added to the 65 g of water, then extracted with 27.0 g ethyl acetate and the organic phase washed with water. Thereafter, ethyl acetate is distilled away, thereby obtaining 2.5 g of 2-methyl-acrylic acid 2-(9-hydroxy-9H-thioxanthen-2-yloxy)-ethyl ester

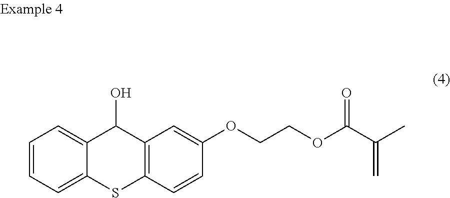 [SMILES: C=C(C)C(=O)OCCOc1ccc2c(c1)C(O)c1ccccc1S2]

A solution containing 5.0 g of alpha-methacryloyloxy-gamma-butylolactone, 6.03 g of 2-methyladamantane-2-methacrylate, and 4.34 g of 3-hydroxyadamantane-1-methacrylate, 0.51 g of dimethyl-2, 2′-azobis(2-methylpropionate), and 26.1 g of tetrahydrofuran is prepared. The prepared solution is added for 4 hours to 20.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 160 g of hexane and 18 g of tetrahydrofuran while vigorously stirring precipitates the copolymer. The copolymer is isolated by filtration. Purification of the copolymer is carried out by vacuum drying following two washings by 70 g of hexane, thereby obtaining 8.5 g of white powder of the copolymer (Resin A).

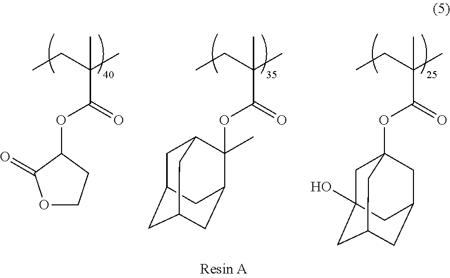

A solution containing 0.98 g of 2-{4-[(2,4-dimethoxy-phenyl)-(1-ethoxy-ethoxy)-methyl]-phenoxy}-ethyl ester, 3.0 g of alpha-methacryloyloxy-gamma-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2,2′-azobis(2-methylpropionate) and 11.2 g of tetrahydrofuran is prepared. The prepared solution is added dropwise for 4 hours to 8.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran while vigorously stirring precipitates the copolymer. The copolymer is isolated by filtration. Purification of the copolymer is carried out by vacuum drying following two washings by 40 g of hexane, thereby obtaining 7.1 g of white powder of the copolymer (Resin B). Since the diarylmethanol moiety functioning as an AGE in Resin B is protected by a protecting group, Resin B has a long-term stability relatively higher than Resin A. In the meantime, the diarylmethanol moiety develops the AGE function by having the protecting group decomposed by acid generated from the PAG.

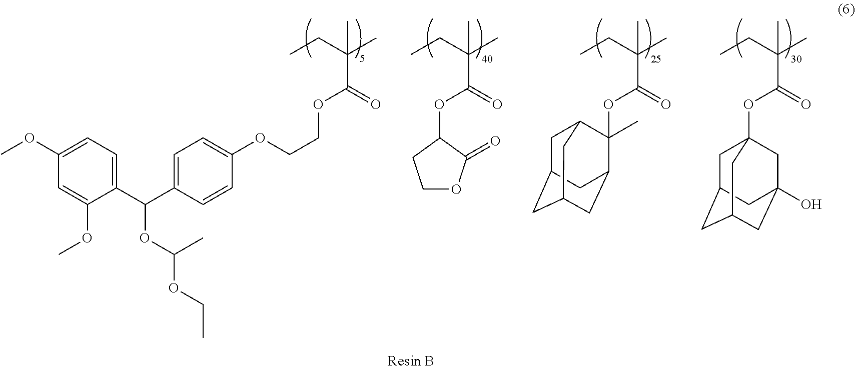

A solution containing 0.76 g of 2-Methyl-acrylic acid 2-(9-hydroxy-9H-thioxanthen-2-yloxy)-ethyl ester, 3.0 g of alpha-methacryloyloxy-gamma-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2, 2′-azobis(2-methylpropionate) and 11.2 g of tetrahydrofuran is prepared. The prepared solution is added dropwise for 4 hours to 8.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran while vigorously stirring precipitates the copolymer. The copolymer is isolated by filtration. Purification of the copolymer is carried out by vacuum drying following two washings by 40 g of hexane, thereby obtaining 5.1 g of white powder of the copolymer.

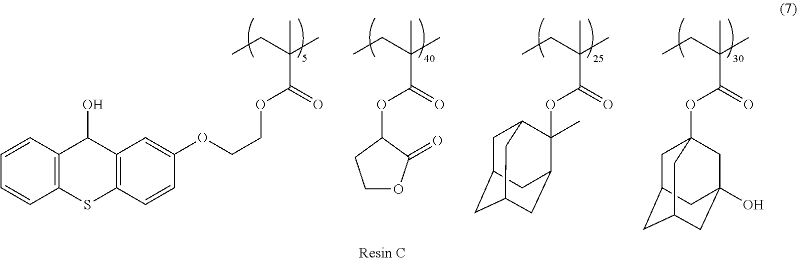

A solution containing 3.0 g of alpha-methacryloyloxy-gamma-butylolactone, 2.6 g of 2-methyladamantane-2-methacrylate, 3.1 g of 3-hydroxyadamantane-1-methacrylate, 1.1 g of 5-phenyl-dibenzothiophenium 1,1-difluoro-2-(2-methyl-acryloyloxy)-ethanesulfonate, 0.20 g of butyl mercaptane, 0.51 g of dimethyl-2,2′-azobis(2-methylpropionate) and 12.2 g of tetrahydrofuran is prepared. 5-phenyl-dibenzothiophenium 1,1-difluoro-2-(2-methyl-acryloyloxy)-ethanesulfonate functions as a PAG moiety. The prepared solution is added dropwise for 4 hours to 8.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran while vigorously stirring precipitates the copolymer. The copolymer is isolated by filtration. Purification of the copolymer is carried out by vacuum drying following two washings by 40 g of hexane and two washings by methanol, thereby obtaining 5.7 g of white powder of the copolymer (Resin D).

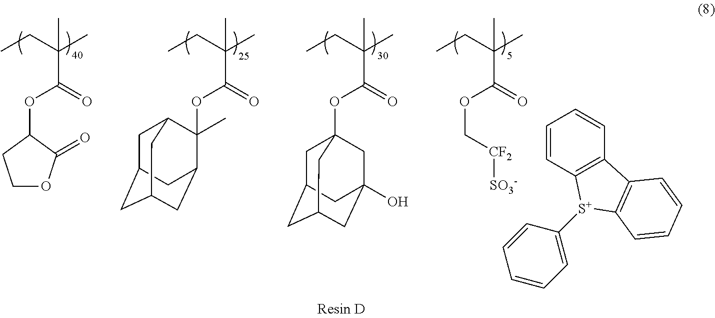

Preparation of Samples for Evaluation (the “Evaluation Samples”)

Each of Evaluation Samples 1-10 is prepared by dissolving 24.1 mg of triphenylsulfonium nonafluorobutanesulfonate (TPS-PFBS), 24.9 mg of 5-phenyl-dibenzothiophenium nonafluorobutanesulfonate (PBpS-PFBS) or 24.1 mg of diphenyliodonium nonafluorobutanesulfonate (DPI-PFBS) as a photoacid generator (PAG) and 600 mg of Resins A, B, and C in 8000 mg of cyclohexanone, respectively, while each of Evaluation Samples 17-19 is prepared by dissolving 600 mg of Resin D in 8000 mg of cyclohexanone. Table 1 shows the details of the sample compositions.

TABLE 1
Evaluation Samples for evaluation for efficiencies of patterning

| | Resin | PAG | Additive | Solvent |
|---|---|---|---|---|
| Evaluation | Resin A | TPS-PFBS | | Cyclohexanone |
| Sample 1 | | | | |
| Evaluation | | | Example 1 | |
| Sample 2 | | | | |
| Evaluation | | | Example 2 | |
| Sample 3 | | | | |
| Evaluation | | DPI-PFBS | Example 1 | |
| Sample 4 | | | | |
| Evaluation | | | Example 2 | |
| Sample 5 | | | | |
| Evaluation | | PBpS-PFBS | Example 1 | |
| Sample 6 | | | | |
| Evaluation | | | Example 2 | |
| Sample 7 | | | | |
| Evaluation | Resin B | PBpS-PFBS | — | |
| Sample 8 | | | | |
| Evaluation | Resin C | | | |
| Sample 9 | | | | |
| Evaluation | Resin D | — | Example 2 | |
| Sample 10 | | | | |

Evaluation of Sensitivity

Before applying each of the Evaluation Samples to an Si wafer, hexamethyldisilazane (HMDS, Tokyo Chemical Industry) is spin-coated at 2000 rpm for 20 seconds on the surface of the Si wafer and baked at 110 degrees Celsius for 1 minute. Then, each of the Evaluation Samples is spin-coated on the surface of the Si wafer, which has been treated with HMDS at 4000 rpm for 20 seconds to form a coating film. The prebake of the coating films is performed at 110 degrees Celsius for 60 seconds. Then, the coating film of the Evaluation Sample is exposed to 100 keV EB output from EB radiation source through the 2-micrometer line and space-patterned mask. After the EB exposure, the coating film is exposed to a white LED light with delay of 0.5-1.0 microseconds from the EB exposure to excite ketyl radical formed by the EB exposure during its lifetime. Next, an irradiation of the coating film with a UV light is carried out at an ambient condition. After the UV light exposure, a post-exposure-bake (PEB) is carried out at 100 degrees Celsius for 60 seconds. The coating film is developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating film measured using a film thickness measurement tool is approximately 150 nm.

Sensitivity (E₀ sensitivity) is evaluated by measuring the total doses to form a pattern comprising 2-micrometer lines, where the thickness of the coating film is not zero, and 2-micrometer spaces, where the thickness of the coating film is zero, using an EB-engine (trademark) (Hamamatsu Photonics) and white LED light (bright line is mainly from 400 nm to 700 nm) under vacuum condition and the UV exposures using FL-6BL (bright line is mainly from 320 nm to 380 nm, Toshiba) under ambient condition.

Even if the UV exposure is carried out without a mask, 2-micrometer spaces are formed in the parts of the coating film that have been exposed to the EB and LED. This indicates that a product functioning as a photosensitizer for the UV light is generated in the parts exposed to the EB and LED light. On the other hand, 2-micrometer spaces are not formed by UV exposure without LED light exposure following EB exposure. The results indicate that the reduction of sulfonium cation of the PAG and the PAG moiety with excitation of ketyl radical formed from corresponding precursor by LED light exposure is relatively effective, while the efficiency of reduction of the sulfonium cation without excitation of the ketyl radical is low. In other words, the excitation of ketyl radical by a visible light exposure is considered to enhance its reducing character.

Table 2 shows the total doses corresponding to E₀ sensitivities measured for the Evaluation Samples. Table 2 indicates that, basically, the doses of the EB exposure decreases with increase of the doses of the UV light exposures following the LED light exposures.

TABLE 2
The doses for E₀ light by an EB, LED and
UV exposures for the Evaluation Samples.

Total doses for E₀

| | Evaluation | EB dose | LED dose | UV dose |
|---|---|---|---|---|
| Run | Sample | [μC/cm²] | [lm\check{ }s] | [mJ/cm²] |
| 1 | 1 | 30 | 0 | 0 |
| 2 | 2 | 30 | 0 | 0 |
| 3 | | 27 | 1520 | 0 |
| 4 | | 27 | 1520 | 3350 |
| 5 | 3 | 27 | 1520 | 0 |
| 6 | | 27 | 1520 | 3350 |
| 7 | 4 | 23 | 0 | 0 |
| 8 | | 19 | 1520 | 0 |
| 9 | | 18 | 1520 | 520 |
| 10 | 5 | 23 | 0 | 0 |
| 11 | | 19 | 1520 | 0 |
| 12 | | 16 | 0 | 520 |
| 13 | | 12 | 1520 | 520 |
| 14 | 6 | 26 | 0 | 0 |
| 15 | | 22 | 1520 | 0 |
| 16 | | 21 | 1520 | 520 |
| 17 | 7 | 26 | 0 | 0 |
| 18 | | 22 | 1520 | 0 |
| 19 | | 26 | 0 | 520 |
| 20 | | 15 | 1520 | 520 |
| 21 | 8 | 26 | 0 | 0 |
| 22 | | 20 | 1520 | 0 |
| 23 | | 26 | 0 | 520 |
| 24 | | 14 | 1520 | 520 |
| 25 | 9 | 26 | 0 | 0 |
| 26 | | 20 | 1520 | 0 |
| 27 | | 26 | 0 | 520 |
| 28 | | 10 | 1520 | 520 |
| 29 | 10 | 26 | 0 | 0 |
| 30 | | 20 | 1520 | 0 |
| 31 | | 26 | 0 | 520 |
| 32 | | 14 | 1520 | 520 |

The results of the Evaluation Samples 2-10 in Table 2 indicate that visible light exposure enhances sensitivity of the EB lithography by exciting the corresponding ketyl radicals by visible light absorption. Therefore, ketyl radicals become reducing species by excitation for sulfonium type PAG. The ketyl radical generated from Example 2 contained in Evaluation Sample 5 can donate its electron to DPI-PFBS without excitation of the ketyl radical and is easily converted to a corresponding benzophenone. Therefore, the doses of EB can be reduced by performing an UV irradiation of the corresponding benzophenone even if no irradiation of the ketyl radical with LED is carried out. In other words, the iodonium PAG is reduced by the ketyl radical in the ground state because it has high reduction potential higher than oxidation potential of ketyl radicals in the ground state. In addition, sensitivities of Evaluation Samples 4-10 increase by UV exposure after EB and visible light exposure because DPI-PFBS and PBpS-PFBS are reduced by excited ketone from oxidized precursor by EB and visible light exposure.

Ketyl radicals generated from Examples 1-4 by having alpha hydrogen atoms of hydroxyl groups abstracted are reducing characters for sulfonium and iodonium type PAG by generated excited state by visible light exposure because ketyl radical has absorption in visible light wavelength. In addition, ketones that are oxidized to form corresponding ketyl radicals exhibit longer absorption bands than the corresponding alcohols. Therefore, utilization of Examples 1-4 as AGEs enable performance of multi-step lithographic exposure that can be used for a variety of devices, such as semiconductor devices and electro-optical devices. Typically, after an EUV light or electron beam is used for a first lithographic exposure, a light with a wavelength longer than the EUV light is used for a second lithographic exposure.

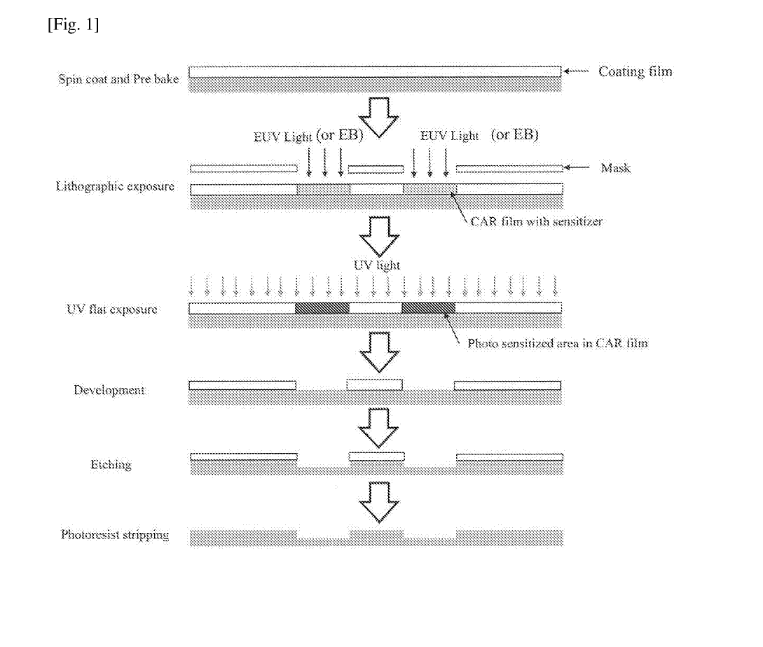

FIG. 1 shows fabrication processes of a device such as integrated circuit (IC) using a photoresist including the acid generation enhancer (AGE) obtained by the processes by the above procedures.

A silicon wafer is provided. The surface of the silicon wafer is oxidized by heating the silicon wafer in the presence of oxygen gas.

A solution of a chemically amplified composition (CAR) including an AGE, resin A, and a PAG is applied to the surface of an Si wafer by spin coating to form a coating film. The coating film is prebaked.

An irradiation of the coating film with an EUV light through a mask is carried out after prebake of the Si wafer. The deprotection reaction of resin A is induced by acid generated by photoreaction of the photoacid generator and assistance by AGE.

After the EUV irradiation of the coating film, an irradiation of the coating film with a light with a wavelength equal to or longer than 300 nm is carried out.

Development of the coating film that has been irradiated with the EUV light and the light with a wavelength equal to or longer than 300 nm is performed after the prebake.

The coating film and the silicon wafer are exposed to plasma. After that, the remaining film is removed.

An electronic device such as an integrated circuit is fabricated utilizing the processes shown in FIG. 1. The deterioration of the device due to the irradiation with a light is suppressed, compared to existing photoresists, since times for irradiation of the coating film is shortened.

1.-15. (canceled)

16. A method for manufacturing a device, the method comprising:
applying a solution of a composition to a substrate such that a coating film including the composition is formed on the substrate; and
performing a second irradiation of the coating film; and
performing a first irradiation of the coating film during a period a lifetime of the intermediate lives after the second irradiation is carried out,
wherein the composition includes: a reagent generating an intermediate, and a precursor enhancing a generation of a first chemical species by a first irradiation of the intermediate with at least one of a first electromagnetic ray of which wavelength is a first wavelength and a first particle ray.

17. (canceled)

18. The method according to claim 16, further comprising:
performing the second irradiation of the coating film such that a first portion of the coating film is irradiated with the at least one of a second electromagnetic ray and a second particle ray while a second portion of the coating film is not irradiated with the at least one of the second electromagnetic ray and the second particle ray; and
removing the first portion or the second portion,
wherein:
the second irradiation is performed prior to the first irradiation; and
the intermediate is generated by the second irradiation.

19. The method according to claim 16, further comprising:
performing a third irradiation of the coating film with at least one of a third electromagnetic ray and a third particle ray after performing the first irradiation,
wherein a product generated from the intermediate is excited by the third irradiation.

20. The method according to claim 18, further comprising:
etching the substrate such that a third portion of the substrate on which the first portion has been present is etched.

21. The method according to claim 16, wherein the second irradiation is performed with an EUV light or an EB.

22. The method according to claim 16, wherein the first irradiation is performed with an LED light.

23. The method according to claim 21, wherein the first irradiation is performed with an LED light.

24. The method according to claim 19, wherein the third irradiation is performed with a UV light.
